(19) United States
(12) Patent Application Publication
(10) Pub. No.: US 2008/0073692 A1
(43) Pub. Date: Mar. 27, 2008

(54) SEMICONDUCTOR CHIP AND METHOD OF FORMING THE SAME

(75) Inventors: Jang-Hee LEE, Gyeonggi-do (KR); Geum-Jung SEONG, Seoul (KR); Byung-Hee KIM, Seoul (KR); Tae-Ho CHA, Gyeonggi-do (KR); Hee-Sook PARK, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/773,362

(22) Filed: Jul. 3, 2007

(30) Foreign Application Priority Data
Jul. 3, 2006 (KR) 2006-62118

(51) Int. Cl. H01L 29/788; H01L 21/336

(52) U.S. Cl. 257/315; 438/257; 257/E21.422; 257/E29.3

(57) ABSTRACT

A method of forming a semiconductor device includes sequentially first and second tungsten silicide layers on a silicon layer. The first tungsten silicide layer is in a substantially amorphous state and a ratio of tungsten to silicon in the first tungsten silicide layer is about 1:4.5˜about 1:9.

### CROSS-REFERENCE TO RELATED APPLICATIONS

This application claims the benefit of foreign priority under 35 U.S.C. §119 to Korean Patent Application No. 2006-62118 filed on Jul. 3, 2006, the entirety of which is hereby incorporated by reference.

### BACKGROUND

1. Field of Invention

Embodiments of the present invention relate generally to semiconductor devices and methods of forming the same. More specifically, embodiments of the present invention relate to a semiconductor device with a conductive pattern made of silicon and metal silicide stacked sequentially, and to a method of forming the same.

2. Description of the Related Art

Conventionally, conductive patterns used in a semiconductor device require a low electrical resistance to enhance an operation speed of the semiconductor device and reduce power dissipation. Conductive patterns made of silicon and tungsten silicide stacked sequentially have been introduced to achieve a low electrical resistance. A pattern made of silicon and tungsten silicide stacked sequentially may be defined as “polycide”, which can be used as a gate of a field effect transistor (hereinafter referred to “transistor”). The silicon in the polycide serves to control characteristics of the transistor and the tungsten silicide serves to lower a resistance of the gate and enhance an operation speed of the transistor. A conventional method for forming a gate of polycide will now be described below with respect to FIGS. 1 through 3.

Referring to FIG. 1, a gate oxide layer 2 is formed on a semiconductor substrate 1. A polysilicon layer 3 is deposited on the gate oxide layer 2. Referring to FIG. 2, a tungsten silicide layer 4 is formed on the semiconductor substrate 1.

After forming the tungsten silicide layer 4, a post-silane treatment using silane gas is performed on the semiconductor substrate 1 to reduce a stress between the tungsten silicide layer 4 and the polysilicon layer 3. If the post-silane treatment is not performed, the stress may cause lifting of the tungsten silicide layer 4.

However, the post-silane treatment may result in additional growth of the polysilicon layer 3 below the tungsten silicide layer 4. Conventionally, the tungsten silicide layer 4 grows with a columnar grain structure. During the post-silane treatment, silicon sources penetrate an interface between the tungsten silicide layer 4 and the polysilicon layer 3 along columnar grain boundaries of the tungsten silicide layer 4 to form an increased-thickness polysilicon layer 3′ below the tungsten silicide layer 4. The increased-thickness polysilicon layer 3′ has a larger thickness than the polysilicon layer 3 just after being deposited. In FIG. 2, reference numeral 5 denotes the portion of the increased-thickness polysilicon layer 3′ grown during the post-silane treatment.

Referring to FIG. 3, the tungsten silicide layer 4 and the increased-thickness polysilicon layer 3′ are successively patterned to form a polysilicon pattern 3a and a tungsten silicide pattern 4a, which are stacked sequentially to constitute a gate electrode 6.

According to the above-described method, the post-silane treatment may result in additional growth of the polysilicon layer 3 below the tungsten silicide layer 4. Thus, the gate electrode 6 may increase in height. With the recent trend toward higher integration density of semiconductor devices, the increased height of the gate electrode 6 may make it difficult to fabricate semiconductor devices. Moreover, characteristics of a transistor including the gate electrode 6 may become degraded as the height of the gate electrode 6 increases.

### SUMMARY

One embodiment exemplarily described herein may generally be characterized as a semiconductor device that includes a silicon pattern disposed on a substrate; a first tungsten silicide pattern disposed on the silicon pattern; and a second tungsten silicide pattern disposed on the first tungsten silicide pattern. The first tungsten silicide pattern may be in a substantially amorphous state and a ratio of tungsten to silicon in the first tungsten silicide pattern may be about 1:4.5˜about 1:9.

Another embodiment exemplarily described herein may generally be characterized as a method of forming a semiconductor device that includes forming a silicon layer on a substrate; forming a first tungsten silicide layer on the silicon layer; and forming a second tungsten silicide layer on the first tungsten silicide layer. The first tungsten silicide pattern may be in a substantially amorphous state and have a ratio of tungsten to silicon of about 1:4.5˜about 1:9.

### BRIEF DESCRIPTION OF THE DRAWINGS

FIGS. 1 through 3 are cross-sectional views illustrating a conventional method of forming a semiconductor device with a polycide gate;

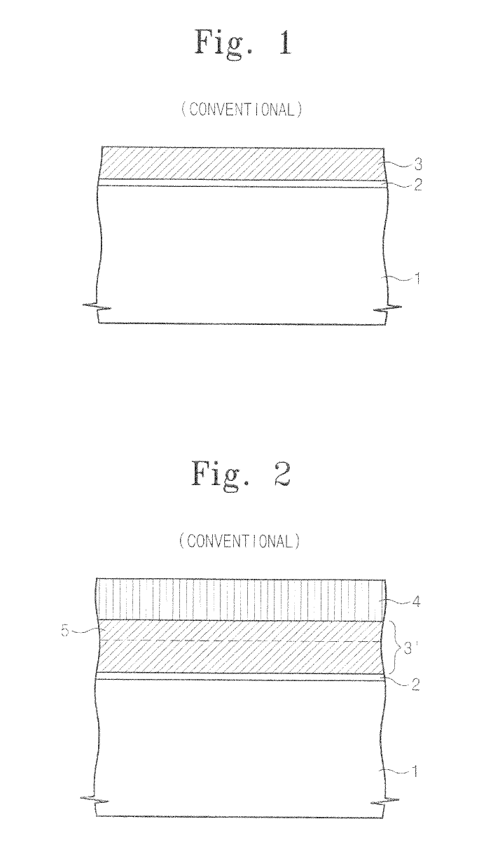

FIGS. 4 through 6 are cross-sectional views illustrating an exemplary method of forming a semiconductor device according to one embodiment;

FIG. 7 is a flowchart of the method of a forming tungsten silicide layer as shown in FIGS. 4 through 6;

FIG. 8 illustrates scanning electron microscope (SEM) photos for explaining a first test performed according to one embodiment;

FIG. 9 illustrates SEM photos for explaining a second test performed according to another embodiment; and

FIGS. 10 through 12 are cross-sectional views illustrating a method of forming a semiconductor device according to another embodiment.

### DETAILED DESCRIPTION

Exemplary embodiments of the present invention will now be described more fully hereinafter with reference to the accompanying drawings. These embodiments, however, may be realized in many different forms and should not be construed as limited to the realizations set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

### EMBODIMENT 1

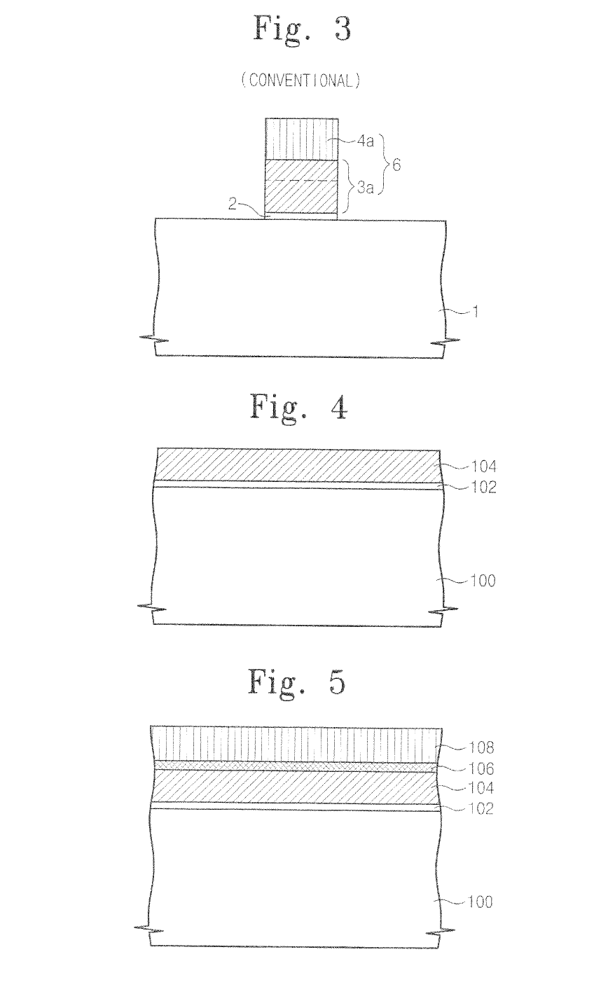

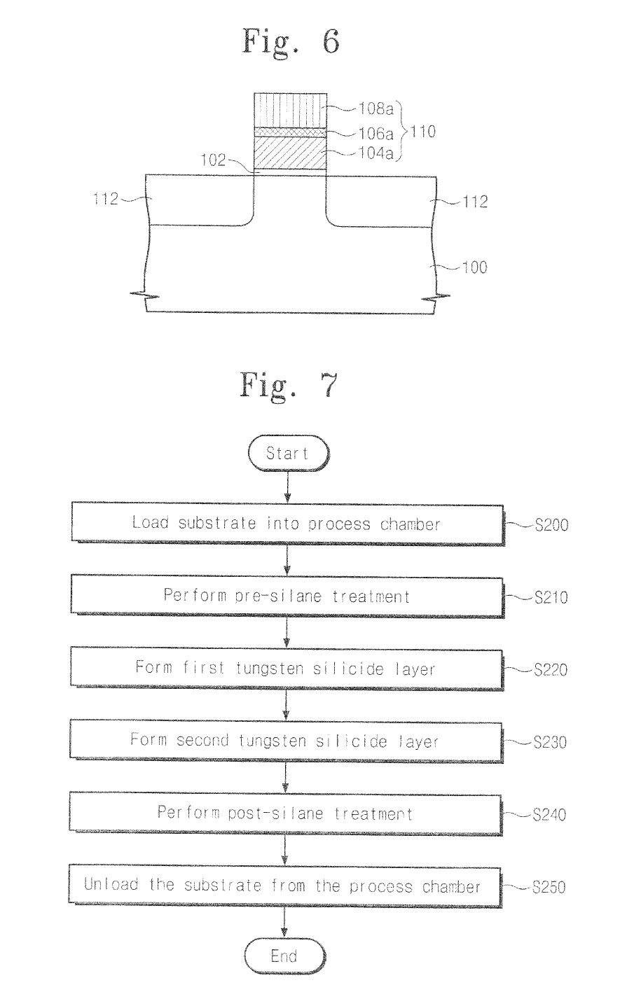

FIGS. 4 through 6 are cross-sectional views illustrating a method of forming a semiconductor device according to one embodiment. FIG. 7 is a flowchart of the method of a forming tungsten silicide layer as shown in FIGS. 4 through 6.

Referring to FIG. 4, a gate insulator 102 may be formed on a semiconductor substrate (hereinafter referred to as “substrate”) 10. A silicon layer 104 may be formed on the gate insulator 102. The gate insulator 102 may include, for example, silicon oxide, and the silicon layer 104 may include, for example, polysilicon. In one embodiment, the silicon layer 104 may be doped with dopants. The silicon layer 104 may be doped by means of, for example, an ion implanting process, an in-situ process, or the like or a combination thereof.

Referring to FIG. 5, a first tungsten silicide layer 106 and a second tungsten silicide layer 108 are sequentially formed on the silicon layer 104. One exemplary method of forming the first and second tungsten silicide layers 106 and 108 will be described in greater detail with reference to the flowchart illustrated in FIG. 7.

Referring to FIGS. 5 and 7, the substrate 100 including the silicon layer 104 is loaded into a process chamber (S200). Before loading the substrate 100 into the process chamber, a surface of the silicon layer 104 may be cleaned.

After loading the substrate 100 into the process chamber, pre-silane gas is introduced into the process chamber to perform a pre-silane treatment (S210). The pre-silane gas may be mono silane gas (SiH₄) or dichloro-silane gas (SiH₂Cl₂). The pre-silane treatment is performed upon a top surface of the silicon layer 104. During the pre-silane treatment, a flow rate of the pre-silane gas is about 500 sccm to about 2,000 sccm. A process pressure of the pre-silane treatment is about 2 Torr to about 10 Torr and a process duration thereof is about 30 seconds to about 300 seconds.

After the pre-silane treatment is performed, the interior of the process chamber may be purged. A first tungsten source gas, a first silicon source gas and a first inert gas may then be supplied into the process chamber to form the first tungsten silicide layer 106 on the silicon layer 104 (S220). The first tungsten silicide layer 106 may be formed in a substantially amorphous state. In the first tungsten silicide layer 106, a ratio of tungsten to silicon may be about 1:4.5˜about 1:9. In some embodiments, the ratio of tungsten to silicon in the first silicide layer 106 is 1:4.5˜1:9. A thickness of the first tungsten silicide layer 106 may be substantially 20 angstroms or larger. In one embodiment, the thickness of the first tungsten silicide layer 106 may be substantially 20 to about 250 angstroms.

The first tungsten source gas may be WF₆ and the first silicon source gas may be SiH₄ or SiH₂Cl₂. Further, the first inert gas may be argon. A flow rate of the first tungsten source gas may be about 1 seem to about 5 sccm and a flow rate of the first silicon source gas may be about 100 sccm to about 500 sccm. Further, a flow rate of the first inert gas may be about 1,400 sccm to about 3,000 sccm. In some embodiments, the flow rate of the first inert gas may be 1,400 sccm to 3,000 sccm. It has been discovered that the flow rate of the first inert gas may have a significant effect on the tungsten to silicon (W:Si) ratio in the first tungsten silicide layer 106. When the first tungsten silicide layer 106 is formed, a process pressure in the process chamber may be about 0.3 Torr to about 3 Torr and a process temperature therein may be about 550 degrees centigrade to about 650 degrees centigrade. In one embodiment, the process temperature in the process chamber may be about 600 degrees centigrade to about 610 degrees centigrade when the first tungsten silicide layer 106 is formed.

After forming the first tungsten silicide layer 106, a second tungsten source gas, a second silicon source gas and a second inert gas may be introduced into the process chamber to form a second tungsten silicide layer 108 on the first tungsten silicide layer 106 (S230). In the second tungsten silicide layer 108, a ratio of tungsten to silicon may be about 1:1˜about 1:3. A resistivity of the second tungsten silicide layer 108 may be less than a resistivity of the first tungsten silicide layer 106. The second tungsten silicide layer 108 may be formed in a substantially crystalline state.

The second tungsten source gas may be WF₆ and the second silicon source gas may be SiH₄ or SiH₂Cl₂. Further, the second inert gas may be argon gas. A ratio of a flow rate of the second tungsten source gas to a flow rate of the second silicon source gas may be about 1:10˜about 1:40. A flow rate of the second inert gas may be smaller than that of the first inert gas. In some embodiments, the flow rate of the second inert gas may be about 1 sccm to about 1,000 sccm.

After forming the second tungsten silicide layer 108, the interior of the process chamber may be purged. A post-silane treatment may then be performed upon the substrate 100 including the second tungsten silicide layer 108 (S240). In some embodiments, the post-silane treatment may reduce a stress between the first and second tungsten silicide layers 106 and 108 and the silicon layer 104 and decrease the amount of fluorine (F) possibly present within the first and second tungsten silicide layers 106 and 108. The post-silane treatment uses a post-silane gas, which may be, for example, SiH₄ or SiH₂Cl₂. During the post-silane treatment, a flow rate of the post-silane gas may be about 300 sccm to about 1,000 sccm. In some embodiments, the inert gas may flow into the process chamber during the post-silane treatment, in addition to the post-silane gas.

After the post-silane treatment is performed, the substrate 100 may be unloaded from the process chamber (S250). By performing the method as exemplarily described above, the first and second tungsten silicide layers 106 and 108 may be formed on the silicon layer 104.

According to the above-described method, after the first silicide layer 106 is formed on the silicon layer 104, the second tungsten silicide layer 108 is formed. The first silicide layer 106 is formed in a substantially amorphous state such that a ratio of tungsten to silicon is about 1:4.5˜about 1:9. In some embodiments, the ratio of tungsten to silicon in the first silicide layer 106 is 1:4.5˜1:9. Thus, the first tungsten silicide layer 106 prevents silicon within a silicon source from being supplied to the silicon layer 104 when the post-silane treatment is performed. As a result, additional growth of a silicon layer may be suppressed.

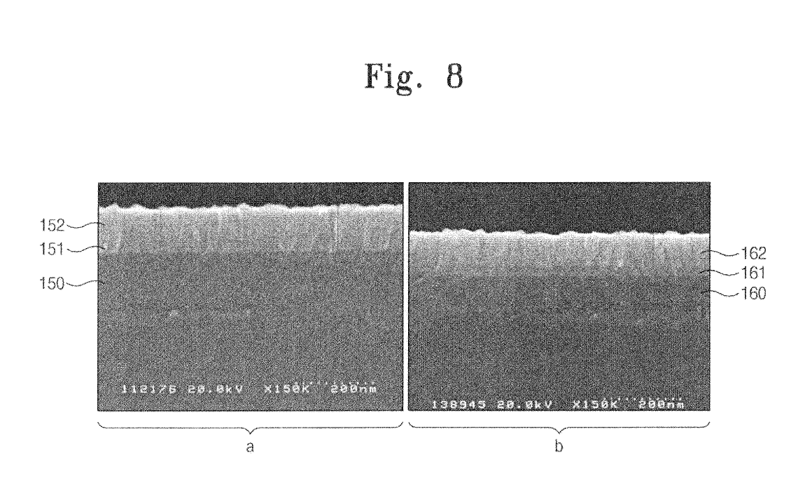

A first test was performed to confirm effects of a semiconductor device formed according to the method exemplarily described above. Specifically, the first test confirmed a ratio of tungsten to silicon in the substantially amorphous first tungsten silicide layer 106. The first test will now be explained in detail below with reference to FIG. 8.

Referring to FIG. 8, samples “a” and “b” were prepared for the first test. To form sample “a”, a silicon layer having a thickness of 800 angstroms was formed on an insulating layer 150. A first tungsten silicide layer 151 having a thickness of 200 angstroms and a second tungsten silicide layer 152 having a thickness of 900 angstroms were then sequentially formed on the silicon layer 150. The post-silane treatment was performed. The first tungsten silicide layer 151 was formed such that a ratio of tungsten to silicon was 1:4.

To form sample “b”, a silicon layer having a thickness of 800 angstroms was formed on an insulating layer 160. A first tungsten silicide layer 161 having a thickness of 200 angstroms and a second tungsten silicide layer 162 having a thickness of 900 angstroms were then sequentially formed on the silicon layer. The first tungsten silicide layer 161 was formed such that a ratio of tungsten to silicon was 1:6.1. The post-silane treatment was performed after forming the second tungsten silicide layer 162. The first tungsten silicide layer 161 was formed by supplying WF₆ at 2 seem, SiH₂Cl₂ at 300 seem and argon gas at 2,600 seem into a process chamber.

As illustrated in FIG. 8, the silicon layer 150 in sample “a” had a thickness of about 1,400 angstroms and the silicon layer 160 of sample “b” had a thickness of about 800 angstroms. Accordingly, the silicon layer 150 of sample “a” grew about 600 angstroms during the post-silane treatment while the silicon layer 160 of sample “b” did not grow during the post-silane treatment. As a result, the SEM photos shows that additional growth of the silicon layer can occur when a ratio of tungsten to silicon in the first tungsten silicide layer is 1:4 or less. Accordingly, a tungsten to silicon ratio in the first tungsten silicide layer 106 illustrated in FIG. 5 can be controlled to be about 1:4.5 or more (e.g., about 1:9 or substantially 1:9) to suppress the additional growth of the silicon layer 104. A tungsten silicide layer having a tungsten to silicon ratio of about 1:9 has a significantly increased resistance.

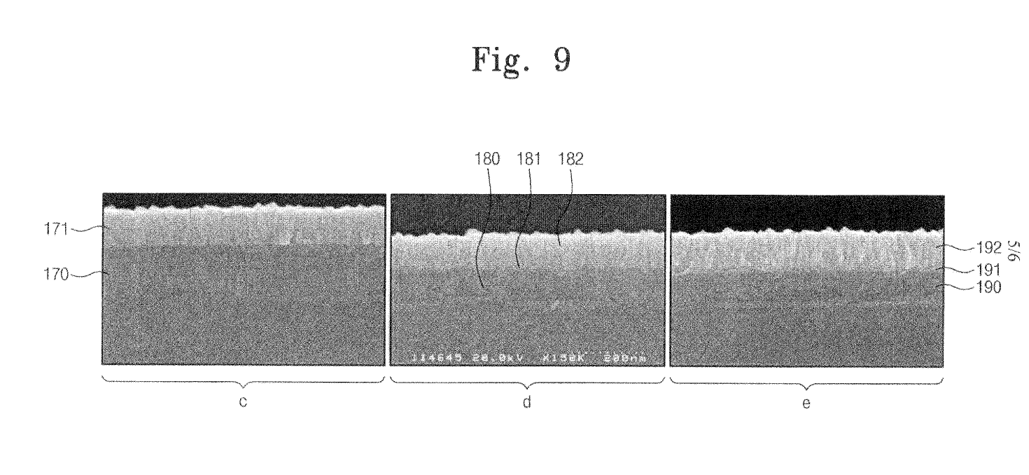

A second test was performed to determine a thickness of the first tungsten silicide layer 106 formed according to the method exemplarily described above. The results of second test will now be explained in detail below with reference to FIG. 9.

Referring to FIG. 9, samples “c”, “d” and “e” were prepared for the second test. To form sample “c”, a silicon layer 170 having a thickness of 800 angstroms was formed on an insulating layer of a substrate. A tungsten silicide layer 171 having a thickness of 1,000 angstroms was then formed. After forming the tungsten silicide layer 171, a post-silane treatment was performed. Accordingly, a substantially amorphous first tungsten silicide layer was not formed for sample “c”. As illustrated, the silicon layer 170 of sample “c” had a thickness of 1,400 angstroms. Thus, the silicon layer 170 of sample “c” grew by about 600 angstroms during the post-silane treatment.

To form sample “d”, a silicon layer 180 having a thickness of 800 angstroms was formed on an insulating layer of a substrate. A first tungsten silicide layer 181 having a thickness of 20 angstroms and a second tungsten silicide layer 182 having a thickness of 980 angstroms were then sequentially formed on the silicon layer 180. A post-silane treatment was performed after forming the second tungsten silicide layer 182. A ratio of tungsten to silicon in the first tungsten silicide layer 181 of sample “d” was 1:6.1. As illustrated, the thickness of the silicon layer 180 of sample “d” was maintained at about 800 angstroms. Accordingly, the silicon layer 180 of sample “d” did not substantially grow during the post-silane treatment.

To form sample “e” a silicon layer 190 having a thickness of 800 angstroms was formed on an insulating layer of a substrate. A first tungsten silicide layer 191 having a thickness of 200 angstroms and a second tungsten silicide layer 192 having a thickness of 800 angstroms were then sequentially formed on the silicon layer 190. A post-silane treatment was performed after forming the second tungsten silicide layer 192. A ratio of tungsten to silicon in the first tungsten silicide layer 191 of the sample “e” was 1:6.1. As illustrated, the silicon layer 100 of the sample “e” was also maintained at a thickness of about 800 angstroms. Accordingly, the silicon layer 190 of sample “e” did not substantially grow during the post-silane treatment.

As a result of the second test, it can be understood that the first tungsten silicide layer 106 illustrated in FIG. 5 can be formed to a thickness of at least about 20 angstroms to suppress the additional growth of silicon. In some embodiments, the first tungsten silicide layer 106 has a thickness of at most about 250 angstroms such that the second tungsten silicide layer 108 having a low resistance can be sufficiently thick.

In some embodiments, the post-silane treatment can significantly affect a ratio of tungsten to silicon in the first tungsten silicide layer 106. In other words, the post-silane treatment and at least one of flow rates of gases (i.e., first tungsten source gas, first silicon source gas and first inert gas) for forming the first tungsten silicide layer 106 may be significant factors to control a ratio of tungsten to silicon in the first tungsten silicide layer 106.

Referring to FIG. 6, the second tungsten silicide layer 108 the first tungsten silicide layer 106 and the silicon layer 104 may be successively patterned to form a silicon pattern 104a, a first tungsten silicide pattern 106a and a second tungsten silicide pattern 108a, respectively. The silicon pattern 104a, first tungsten silicide pattern 106a and second tungsten silicide pattern 108a may be sequentially stacked to constitute a gate electrode 110. Using the gate electrode 110 as a mask, dopant ions may be introduced to form dopant-doped regions 112 within portions of the substrate 100 adjacent to opposite sides of the gate electrode 110.

The gate electrode 110 may be disposed on the substrate 100 with the gate insulator 102 interposed therebetween. As mentioned above, the gate electrode 110 may include the silicon pattern 104a, the first tungsten silicide pattern 106a and the second tungsten silicide pattern 108a which are stacked sequentially. The first tungsten silicide pattern 106a is in a substantially amorphous state. A ratio of tungsten to silicon in the first tungsten silicide pattern 106a may be about 1:4.5˜about 1:9. In some embodiments, the ratio of tungsten to silicon in the first tungsten silicide pattern 106a may be 1:4.5˜1:9. The first tungsten silicide pattern 106a has a thickness ranging from about 20 angstroms to about 250 angstroms. In some embodiments, the first tungsten silicide pattern 106a has a thickness ranging from 20 angstroms to 250 angstroms. The second tungsten silicide layer 108a may be in a substantially crystalline state. A ratio of tungsten to silicon in the second tungsten silicide pattern 108a may be about 1:1˜about 1:3.

### EMBODIMENT 2

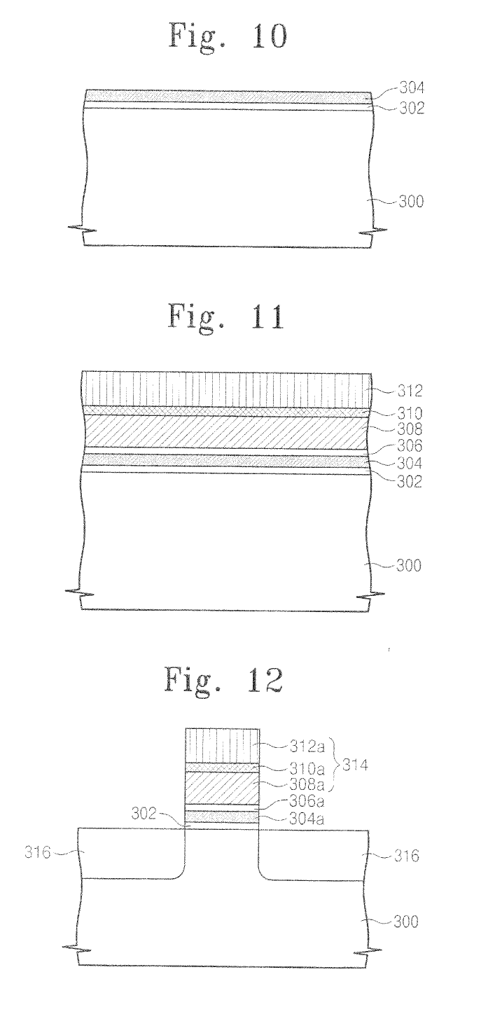

FIGS. 10 through 12 are cross-sectional views illustrating a method of forming a semiconductor device according to another embodiment. In the illustrated embodiment, the semiconductor device may be a non-volatile memory cell.

Referring to FIG. 10, a gate insulator 302 may be formed on a substrate 300. A preliminary charge storage layer 304 may be formed on the gate insulator 302. The gate insulator 302 may include, for example, silicon oxide. In one embodiment, the gate insulator 302 may be a thermal oxide. In one embodiment, the preliminary charge storage layer 304 may include, for example, a trap insulator having deep-level traps. In this case, the preliminary charge storage layer 304 may be formed on the entire surface of the substrate 100. In another embodiment, the preliminary charge storage layer 304 may include, for example, silicon. In this case, the preliminary charge storage layer 304 may exhibit a linear shape extending in one direction on the substrate 304.

Referring to FIG. 11, a blocking insulating layer 306 may be formed on the entire surface of the substrate 300 including the preliminary charge storage layer 304. In this case, the blocking insulating layer 306 may have a larger thickness than the gate insulator 302. In one embodiment, the blocking insulating layer 306 may include an insulator having a higher dielectric constant than the gate insulator 302. For example, the blocking insulating layer 306 may include a material such as silicon nitride, an insulative metal oxide (e.g., hafnium oxide, aluminum oxide, etc.), or the like or combinations thereof.

A silicon layer 308 may be formed on the blocking insulating layer 306. The silicon layer 308 may be made of the same material as the silicon layer 104 described in “Embodiment 1”. A first tungsten silicide layer 310 and a second tungsten silicide layer 312 may then be sequentially formed on the silicon layer 308. The first tungsten silicide layer 310 may have the same characteristics as the first tungsten silicide layer 106 described in “Embodiment 1”. For example, the first tungsten silicide layer 310 may be substantially amorphous and a ratio of tungsten to silicon in the first tungsten silicide layer 310 may be about 1:4.5˜about 1:9. In some embodiments, the ratio of tungsten to silicon in the first tungsten silicide layer 310 is 1:4.5˜1:9. A method of forming the first tungsten silicide layer 310 may be identical to that of forming the first tungsten silicide layer 106. The second tungsten silicide layer 312 may have the same characteristics as the second tungsten silicide layer 108 described in “Embodiment 1”. Further, a method of forming the second tungsten silicide layer 312 may be identical to that of forming the second tungsten silicide layer 108.

The first and second tungsten silicide layers 310 and 312 may be formed by means of the same method as exemplarily described with reference to the flowchart illustrated in FIG. 7. Before forming the first tungsten silicide layer 310, a pre-silane treatment (S210 of FIG. 7) may be performed on a surface of the silicon layer 308. Moreover, after forming the second tungsten silicide layer 312, a post-silane treatment (S240 of FIG. 7) may be performed on the substrate 300.

The first tungsten silicide layer 310 may prevent the silicon layer 308 from growing during the post-silane treatment.

Referring to FIG. 12, the second tungsten silicide layer 312, the first tungsten silicide layer 310, the silicon layer 308, the blocking insulating layer 306 and the preliminary charge storage layer 304 may be successively patterned to form a charge storage pattern 304a, a blocking insulating pattern 306a and a gate electrode 314, which are stacked sequentially. The gate electrode 314 may include a silicon pattern 308a, a first tungsten silicide pattern 310a and a second tungsten silicide pattern 312a, which are stacked sequentially.

Using the gate electrode 314 as a mask, dopant ions may be introduced to form dopant-doped regions 316 within portions of the substrate 300 adjacent to opposite sides of the gate electrode 314.

Referring to FIG. 12, the gate electrode 314 is disposed on the substrate 300 with the charge storage pattern 304a interposed therebetween. The gate insulator 302 is interposed between the charge storage pattern 304a and the substrate 300 and the blocking insulating pattern 306a is interposed between the charge storage pattern 304a and the gate electrode 314. Charges may tunnel through the gate insulator 302. The gate electrode 314 may include a silicon pattern 308a, a first tungsten silicide pattern 310a and a second tungsten silicide pattern 312a, which are stacked sequentially.

The first tungsten silicide pattern 310a is substantially amorphous and a ratio of tungsten to silicon in the first tungsten silicide layer 310a is about 1:4.5˜about 1:9. In some embodiments, the ratio of tungsten to silicon in the first tungsten silicide pattern 310a is 1:4.5˜1:9. The other components have the same characteristics as described in the foregoing method.

While exemplary embodiments have been described where a silicon layer, a first tungsten silicide layer and a second tungsten silicide layer are applied to a field effect transistor and a non-volatile memory cell, it will be appreciated that the aforementioned silicon layer, first tungsten silicide layer and second tungsten silicide layer may be applied to wirings such as, for example, bitlines.

As exemplarily described above, first and second tungsten silicide layers may be sequentially formed on a silicon layer. The first tungsten silicide layer is substantially amorphous and a ratio of tungsten to silicon in the first tungsten silicide layer may be about 1:4.5˜about 1:9. Thus, even when a post-silane treatment is performed, the first tungsten silicide layer may effectively block a silicon source to prevent the silicon layer from growing to increase the thickness of an underlying silicon layer.

Although the present invention has been described in connection with the embodiments of the present invention illustrated in the accompanying drawings, it is not limited thereto. It will be apparent to those skilled in the art that various substitutions, modifications sand changes may be made without departing from the scope and spirit of the invention.

What is claimed is:

1. A semiconductor device comprising:
a silicon pattern disposed on a substrate;
a first tungsten silicide pattern disposed on the silicon pattern; and
a second tungsten silicide pattern disposed on the first tungsten silicide pattern,
wherein the first tungsten silicide pattern is in a substantially amorphous state and a ratio of tungsten to silicon in the first tungsten silicide pattern is about 1:4.5˜about 1:9.

2. The semiconductor device as recited in claim 1, wherein the first tungsten silicide pattern has a thickness of about 20 angstroms to about 250 angstroms.

3. The semiconductor device as recited in claim 1, wherein a ratio of tungsten to silicon in the second tungsten silicide pattern is about 1:1˜about 1:3.

4. The semiconductor device as recited in claim 3, wherein the second tungsten silicide pattern is in a substantially crystalline state.

5. The semiconductor device as recited in claim 1, wherein the silicon pattern, the first tungsten silicide pattern and the second tungsten silicide pattern constitute a gate electrode, the semiconductor device further comprising:
a gate insulator interposed between the silicon pattern and the substrate: and
a dopant-doped region formed within a portion of the substrate adjacent to a side of the gate electrode.

6. The semiconductor device as recited in claim 5, further comprising:
a charge storage pattern interposed between the gate insulator and the gate electrode; and
a blocking insulating pattern interposed between the charge storage pattern and the gate electrode.

7. The semiconductor device as recited in claim 6, wherein the charge storage pattern comprises one of a trap insulating pattern and a floating gate.

8. A method of forming a semiconductor device, comprising:
forming a silicon layer on a substrate;
forming a first tungsten silicide layer on the silicon layer; and
forming a second tungsten silicide layer on the first tungsten silicide layer,
wherein the first tungsten silicide pattern is in a substantially amorphous state and a ratio of tungsten to silicon in the first tungsten silicide pattern is about 1:4.5˜about 1:9.

9. The method as recited in claim 8, wherein forming the first and second tungsten silicide layers comprises:
loading a substrate including the silicon layer into a process chamber;
introducing a first tungsten source gas, a first silicon source gas and a first inert gas into the process chamber to form the first tungsten silicide layer;
introducing a second tungsten source gas, a second silicon source gas and a second inert gas into the process chamber to form the second tungsten silicide layer; and
unloading the substrate from the process chamber.

10. The method as recited in claim 9, further comprising, before unloading the substrate from the process chamber:
introducing post-silane gas into the process chamber to perform a post-silane treatment.

11. The method as recited in claim 9, wherein a flow rate of the first tungsten source gas is about 1 sccm to about 5 sccm; a flow rate of the first silicon source gas is about 100 sccm to about 500 sccm; and a flow rate of the first inert gas is about 1,400 sccm to about 3,000 sccm.

12. The method as recited in claim 11, further comprising, before forming the first tungsten silicide layer:
introducing pre-silane gas into the process chamber to perform a pre-silane treatment.

13. The method as recited in claim 12, wherein a flow rate of the pre-silane gas is about 500 sccm to about 2,000 sccm and a flow duration thereof is about 30 seconds to about 300 seconds.

14. The method as recited in claim 11, wherein the first tungsten source gas comprises tungsten fluoride; the first silicon source gas comprises dichloro silane; and the first inert gas comprises argon.

15. The method as recited in claim 8, wherein the first tungsten silicide layer is formed to have a thickness ranging from about 20 angstroms to about 250 angstroms.

16. The method as recited in claim 8, wherein a ratio of tungsten to silicon in the second tungsten silicide layer is about 1:1˜about 1:3.

17. The method as recited in claim 16, wherein the second tungsten silicide is in a substantially crystalline state.

18. The method as recited in claim 8, further comprising:
forming a gate insulator before forming the silicon layer;
successively patterning the second tungsten silicide layer, the first tungsten silicide layer and the silicon layer to form a silicon pattern, a first tungsten silicide pattern and a second tungsten silicide pattern, respectively, wherein the silicon pattern, first tungsten silicide pattern and second tungsten silicide pattern are sequentially stacked to constitute a gate electrode; and
forming a dopant-doped region within a portion of the substrate adjacent to a side of the gate electrode.

19. The method as recited in claim 18, further comprising, before forming the silicon layer:
forming a preliminary charge storage layer on the gate insulator; and
forming a blocking insulating layer on the entire surface of the substrate,
wherein the silicon layer is formed on the blocking insulating layer and forming the gate electrode comprises successively patterning the second tungsten silicide layer, the first tungsten silicide, the silicon layer, the blocking insulating layer and the preliminary charge storage layer to form a charge storage pattern, a blocking insulating pattern and the gate electrode, wherein the charge storage pattern, the blocking insulating pattern and the gate electrode are stacked sequentially.

20. The method as recited in claim 19, wherein the charge storage pattern comprises one of a trap insulating pattern and a floating gate.
